(19) United States
(12) Patent Application Publication
(10) Pub. No.: US 2023/0009044 A1
(43) Pub. Date: Jan. 12, 2023

(54) LIQUID CHEMICAL SUPPLY DEVICE SYSTEM AND METHOD THEREOF CAPABLE OF PROCESSING GASES CONTAINED THEREIN

(71) Applicant: VERSUM MATERIALS HYT INC., GYEONGGI-DO (KR)

(72) Inventors: SANG JAE YIM, SEOGWIPO-SI (KR); YONG TAE KIM, GYEONGGI-DO (KR); JUN HO KIM, SEOUL (KR); JONG KUE LEE, GYEONGGI-DO (KR); JONG HO JEUNG, GYEONGGI-DO (KR); JI HOON KIM, GYEONGGI-DO (KR)

(21) Appl. No.: 17/784,582

(22) PCT Filed: Dec. 11, 2020
(86) PCT No.: PCT/KR2020/018212

§ 371 Date: Jun. 10, 2022

(30) Foreign Application Priority Data
Dec. 12, 2019 (KR) 10-2019-0165580

(51) Int. Cl. C23C 16/455

(52) U.S. Cl. CPC C23C 16/45561

(57) ABSTRACT

A liquid chemical supply device, system and method capable of processing a gas having first and second canisters connected, respectively, to semiconductor manufacturing apparatus by way of first and second supply lines, to provide liquid chemicals stored therein to the semiconductor manufacturing apparatus; first and second push lines connected to the first and second canisters, respectively, and configured to provide a push gas to the first and second canisters to discharge the chemicals into the first and second supply lines, and a gas processing unit in fluid communication with the first supply line and the second push line, in order for the chemical in the first supply line containing a gas therein to be provided to and stored in the second canister through the second push line.

### TECHNICAL FIELD

The present invention relates to a liquid chemical supply device capable of processing gases, and more particularly, to a liquid chemical supply device capable of continuously supplying liquid chemicals for manufacturing semiconductors stored in a plurality of canisters to a semiconductor manufacturing apparatus without entraining gases therein, which is a cause of defects.

### BACKGROUND ART

The manufacturing process of semiconductors, LEDs, solar cells, etc. mostly consists of a series of processes called CVD (chemical vapor deposition) in CVD tools in which coating materials are chemically deposited on the surface of a substrate using special gases.

In this case, the CVD process is classified into low pressure CVD (LPCVD) for deposition through chemical reactions with special gases at low pressure, atmospheric pressure CVD (APCVD) for deposition at atmospheric pressure, high pressure CVD (HPCVD) for deposition at high pressure, plasma enhanced CVD (PECVD) for deposition through generation of plasma with high voltage, MOCVD (metal organic chemical vapor deposition) for depositing metal organic materials such as gallium, phosphorus, aluminum, and the like, and so on.

These CVD processes universally use liquid chemicals (special chemicals) such as high purity TEOS, TiCL4, TMA, LTO520, TEMAZr, TEMAHf, HBO, 4MS, 3MS, TEB, TEPO, etc. that have hazardous properties such as flammability, corrosivity, toxicity, and so on in liquid form.

The hazardous liquid chemicals as described above are primarily contained in replaceable canisters (referred to as bulk canisters) and then are supplied at a fixed amount to a semiconductor manufacturing apparatus such as a deposition chamber with fixed canisters (referred to as process canisters) fixedly installed in a chemical supply device being used as buffering tanks, and in this case, such a chemical supply method is referred to as a double tank liquid refill (DTLR) type.

A chemical supply device of such a double tank liquid refill type discharges a stored liquid chemical into a dip tube installed therein to thereby provide a fixed amount of the chemical to a semiconductor manufacturing apparatus in a manner of selectively providing a push gas such as inert, high purity argon (Ar), helium (He), hydrogen (H2), and nitrogen (N2) to each canister, thereby pressurizing the inside of the canister.

Referring to FIG. 10, a chemical supply device of a conventional double tank liquid refill type comprises a fixed canister fixedly installed in the chemical supply device, connected to a semiconductor manufacturing apparatus by way of supply lines, and configured to supply a stored liquid chemical to the semiconductor manufacturing apparatus at a fixed amount by a push gas in a first push line, and a replaceable canister installed replaceably in the chemical supply device, connected to the first push line by way of a replenishment line, and configured to replenish the fixed canister with the liquid chemical by the push gas in a second push line to thereby continuously provide the liquid chemical to the semiconductor manufacturing apparatus.

According to the chemical supply device of the conventional double tank liquid refill type configured as described above, the semiconductor manufacturing apparatus can be stably and continuously provided with liquid chemicals through repetitive replacements of the replaceable canister.

However, the conventional supply device has one or more of the following problems. First, if damage, failure, or leakage occurs in the fixed canister itself or the first push line or the supply line connected thereto, it is completely impossible to supply the liquid chemical, which in turn causes a problem of stopping the operation of the semiconductor manufacturing apparatus.

Second, since the fixed canister is managed by a semiconductor manufacturer, unlike the replaceable canister that is provided and managed directly by a chemical supplier, it is difficult for the semiconductor manufacturer to maintain the fixed canister in compliance with safety regulations related to high-pressure containers, which in turn increases the risk of safety accidents.

Third, due to the configuration of the piping circuit, gases introduced into the fixed canister through repair or replacement, or restarting of the supply device cannot be removed due to the configuration of the piping circuit, but are supplied to the semiconductor manufacturing apparatus as they are along with the liquid chemical thereby causing semiconductor defects.

Therefore, there is a need for an improved chemical supply device capable of supplying liquid chemicals more stably and continuously to a semiconductor manufacturing apparatus, capable of manufacturing high quality semiconductors without supplying gases, that may have been introduced during the replacement of a canister or due to damage to a fixed canister supply system, to the semiconductor manufacturing apparatus along with the liquid chemicals, and capable of reducing the occurrence of safety accidents associated with canisters in which the liquid chemicals are stored.

### DISCLOSURE OF INVENTION

### Technical Problem

It is an object of the present invention to solve the problems of using conventional fixed canisters by continuously supplying liquid chemicals to a semiconductor manufacturing apparatus using a plurality of replaceable canisters provided and managed directly by a liquid chemical supplier, and at the same time, to provide a liquid chemical supply device having a means to, and is capable of, processing gases that have been introduced during the replacement of a canister, or can switch supply from one canister to another canister if there is trouble supplying from one of the canisters, and thereby avoid semiconductor defects.

### Solution to Problem

The above object is achieved by a liquid chemical supply device capable of processing a gas, comprising first and second canisters connected, respectively, to semiconductor manufacturing apparatus by way of first and second supply lines, to provide liquid chemicals stored therein to the semiconductor manufacturing apparatus; first and second push lines connected to the first and second canisters, respectively, and configured to discharge the chemicals into the first and second supply lines, when a push gas is provided to the first and second canisters via the first and second push lines, respectively; and a gas processing unit provided between the first supply line and the second push line, in order for the chemical in the first supply line containing a gas therein to be provided to and stored in the second canister through the second push line.

Further, the gas processing unit may comprise a temporary storage tank configured to receive through one side (which may be the top of the storage tank) thereof and accommodate therein the chemical discharged from the first supply line containing the gas therein;

a first inlet pipe configured to selectively communicate between the one side of the temporary storage tank and the first supply line in accordance with operation of one or more 1-1 control valves provided in the first inlet pipe; and

a first outlet pipe configured to selectively communicate between the other side of the temporary storage tank and the second push line in accordance with operation of one or more 1-2 control valves provided in the first outlet pipe.

In alternative embodiments, the pipes could be configured such that a single inlet pipe connected between both first and second supply lines and also connected to the temporary storage container could be used.

The temporary storage tank may be configured to receive through the one side (e.g. top or near the top side) thereof and accommodate therein the chemical discharged from the second supply line containing the gas therein, and then, the chemical in the second supply line containing the gas therein may be provided to and stored in the first canister through the first push line. To do so, the gas processing unit may further comprise a second inlet pipe configured to selectively communicate between the one side (for example, the top or near the top side) of the temporary storage tank and the second supply line in accordance with operation of one or more 2-1 control valves provided on the second inlet pipe; and a second outlet pipe configured to selectively communicate between the other side (for example, the bottom or near the bottom side) of the temporary storage tank and the first push line in accordance with operation of one or more 2-2 control valves provided on the second outlet pipe.

The first canister and the second canister may be replaced, detachably connected and detachable from the liquid chemical supply device after use (when empty or nearly empty) thereof for safe and easy handling of the liquid chemicals.

The liquid chemical supply device may provide the chemical in the first supply line containing the gas therein to the second canister to be stored therein through the second push line in accordance with operation of the 1-1 control valves and the 1-2 control valves, thereby removing the gas from the liquid chemical that is ultimately supplied to the semiconductor manufacturing apparatus.

The liquid chemical supply device may provide the chemical in the second supply line containing the gas therein to the first canister to be stored therein through the first push line by control operation of the 2-1 control valves connecting and controlling the flow of the liquid chemical C having the gas therein to the second inlet pipe from the second supply line, then through the second inlet pipe to the temporary storage tank and from the temporary storage tank through the 2-2 control valves located in the second outlet pipe, preferably at the connection of the second outlet pipe to the first push line connected to the first canister, thereby removing the gas from the liquid chemical that is ultimately supplied to the semiconductor manufacturing apparatus.

The liquid chemical supply device may provide the chemical in the first supply line containing the gas therein to the first canister to be stored therein through the first push line by control operation of the 1-1 control valves and the 2-2 control valves, thereby removing the gas from the liquid chemical that is ultimately supplied to the semiconductor manufacturing apparatus.

The liquid chemical supply device may provide the chemical in the second supply line containing the gas therein to the second canister to be stored therein through the second push line by control operation of the 2-1 control valves and the 1-2 control valves, thereby removing the gas from the liquid chemical that is ultimately supplied to the semiconductor manufacturing apparatus.

In the liquid chemical supply device, a vacuum pump may be configured to cause an interior of the gas processing unit to be in a negative pressure. The vacuum pump is connected to the one side (for example, to the top side via the second inlet pipe as shown) of the gas processing unit, so as to assist when activated, the chemical containing the gas therein to flow smoothly from the first and second supply lines to the gas processing unit.

Also provided herein is a system for supplying a liquid chemical comprising the liquid supply device of any of the preceding claims and one or more semiconductor manufacturing apparatuses, wherein the one or more semiconductor manufacturing apparatuses may be one or more CVD tools and wherein the liquid chemical supplied to the apparatuses may be high purity TEOS, TiCL4, TMA, LTO520, TEMAZr, TEMAHf, HBO, 4MS, 3MS, TEB, or TEPO.

Also provided herein is a method of processing a gas, comprising the steps of providing any of the liquid chemical supply devices or systems disclosed herein; flowing a push gas in said first push line to said first canister having said liquid chemical and said gas therein, and thereby flowing from said first canister said liquid chemical containing said gas to a first supply line; flowing said liquid chemical containing said gas from said first supply line to said gas processing unit; flowing said liquid chemical containing said gas from said gas processing unit through a second push line into said second canister; and storing said liquid chemical containing said gas in said second canister.

The method may provide the additional the step of supplying said one or more semiconductor apparatuses from said second canister while simultaneously performing the step of flowing said liquid chemical containing said gas from said gas treatment unit through said second push line into said second canister, and/or may further comprise the step of temporarily blocking the flow of the push gas in the second push line while performing the step of flowing said liquid chemical containing said gas from said gas treatment unit through said second push line into said second canister.

The method may further comprise, alone or with other steps, the step of switching the supply of the liquid chemical from the second canister to the first canister when the level in the second canister reaches a set value, by flowing push gas through the first push line and into the first canister.

The method may further comprise alone or with other steps, the step of flowing the push gas into the second canister to flow liquid chemical present in the second canister through the gas processing unit and into the first canister while the first canister continues to supply the one or more semiconductor apparatuses until the second canister is exhausted.

Additionally, the method may comprise, alone or with other steps, the steps of terminating the flow of the push gas to the second canister; flowing the push gas to the first canister; and replacing the exhausted second canister while continuing to flow push gas into the first canister to flow liquid chemical present in the first canister to the one or more semiconductor apparatuses.

### Advantageous Effects of Invention

In accordance with the present invention, as first and second canisters, respectively, connected to a semiconductor manufacturing apparatus by way of first and second supply lines and configured to provide stored liquid chemicals, and first and second push lines configured to discharge the chemicals to the first and second supply lines by the pressure of a push gas are provided, and a gas processing unit that is operatively controlled for the chemical in the supply line containing a gas therein to be recovered into or stored in the first or second canister through the push line is provided, with connections to first and second supply lines on one side (the top side) and connections to the first and second push lines on the opposite side (the bottom side) of the gas processing unit. By using a gas processing unit the liquid chemical can be supplied to the semiconductor manufacturing apparatus more stably and continuously, and it is possible to make full use of the chemical in the replaceable canister in which the introduction of gases is problematic during each replacement, to put the responsibility for maintenance of the reusable canisters on the chemical supplier, and furthermore, removing the gases from the liquid chemical that is ultimately supplied to the semiconductor manufacturing apparatus which enables the manufacture of high quality semiconductors.

### BRIEF DESCRIPTION OF DRAWINGS

FIG. 1 is a schematic diagram showing the overall structure and connections within a liquid chemical supply device capable of processing a gas according to one embodiment;

FIG. 2 is a schematic diagram of the liquid chemical supply device of FIG. 1, showing a supply of a liquid chemical by a first canister to a manufacturing apparatus and replacement of an exhausted second canister;

FIG. 3 is a schematic diagram of the liquid chemical supply device of FIG. 1 or 2, showing when a gas at the top of a dip tube in the second canister, after the replacement of the second canister, is flowed to the gas processing unit for processing by the gas processing unit;

FIG. 4 is a schematic diagram of the liquid chemical supply device of any of FIGS. 1-3, showing when the gas processed by the gas processing unit and the liquid chemical are transferred to the first canister through the first push line while the supply of the liquid chemical from the first canister is maintained;

FIG. 5 is a schematic diagram of the liquid chemical supply device of any of FIGS. 1-4, showing when the liquid chemical from the first canister is continuously supplied by the first push line until the liquid chemical of the first canister becomes less than or equal to a set value;

FIG. 6 is a schematic diagram of the liquid chemical supply device of any of FIGS. 1-5, showing when a supply source of the liquid chemical is switched from the first canister to the second canister when the liquid chemical of the first canister remains less than or equal to the set value;

FIG. 7 is a schematic diagram of the liquid chemical supply device of any of FIGS. 1-6 showing when the liquid chemical is transferred from the first canister to the second canister until the first canister is exhausted, while the liquid chemical is supplied from the second canister to the manufacturing apparatus;

FIG. 8 is a schematic diagram of the liquid chemical supply device of any of FIGS. 1-7 showing the replacement of the exhausted first canister while the liquid chemical of the second canister is continuously supplied by the second push line until the liquid chemical of the second canister becomes less than or equal to the set value;

FIG. 9 is a schematic diagram of the liquid chemical supply device of any of FIGS. 1-8 showing when a gas that was present at the top of the dip tube, after the replacement of the first canister is flowed, by the push gas in the first push line to and through the gas processing unit and to the second canister for storage; and

FIG. 10 is a schematic diagram showing the overall structure and connections in a conventional liquid refill chemical supply device having a fixed canister and a refill canister.

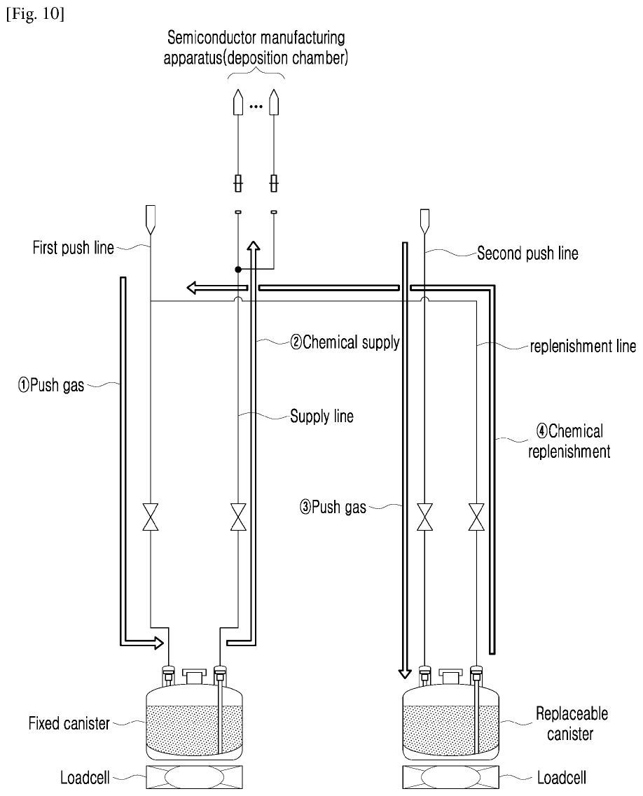

### DESCRIPTION OF REFERENCED NUMERALS AND SYMBOLS

10: Semiconductor manufacturing apparatus

C: Liquid chemical

PG: Push gas

G: Gas contained in a liquid chemical

LC: Load cell

100: Liquid chemical supply device capable of processing a gas

110a, 110b: First and second canisters

112a, 112b: Dip tubes

120a, 120b: First and second supply lines

130a, 130b: First and second push lines

140: Gas processing unit

141: Temporary storage tank

IS: Interior space

142: First inlet pipe

142a, 142b: 1-1 control valves

143: First outlet pipe

143a, 143b: 1-2 control valves

144: Second inlet pipe

144a, 144b: 2-1 control valves

145: Second outlet pipe

145a, 145b: 2-2 control valves

150: Vacuum pump

### MODE FOR THE INVENTION

Hereinafter, preferred embodiments of the present invention will be described in greater detail as follows, with reference to the accompanying drawings. However, in describing the present invention, descriptions of known functions or features will be omitted in order to clearly set forth the subject matter of the present invention.

Terms such as “top (upper),” “bottom (lower),” “left and right (sideways or lateral),” “front (forward),” “back (rear, backward),” etc. used to indicate directions in the description of the invention and claims, etc. are defined based on relative positions in the drawings and between components not for limiting the scope thereof but for convenience of description, and accordingly follow as such, unless otherwise specified. The term “side” can mean any “side”, such as horizontal sides or vertical sides and includes a top side and/or a bottom side. The use of “comprising” or “having” anywhere herein includes the partially closed or closed terms “consisting essentially of” and “consisting of”

A liquid chemical supply device 100 capable of processing a gas according to the present invention is an invention derived to fundamentally solve the problems of using conventional fixed canisters. The liquid chemical supply device 100 can continuously supply a liquid chemical C to a semiconductor manufacturing apparatus 10 using a plurality of replaceable canisters, and process gases or gas G which have been introduced into the device during the replacement of a canister, or due to damage to a supply device that would require a canister change, or the like which would cause semiconductor defects. The term gases or gas G may be used interchangeably herein. The use of gases G may be replaced with gas G anywhere it appears and gas G may be replaced with gases G. The gas G may be an inert gas present within a freshly filled canister to fill the headspace above the liquid chemical in the cannister, and, in some embodiments, the gas or inert gas filling the space in the diptube above the liquid, as provided by the supplier. The inert gas may be any of high purity inert gas or mixtures of the inert gases, such as, high purity argon (Ar), helium (He), hydrogen (H2), and nitrogen (N2) or the like.

By using the liquid chemical supply device 100, the liquid chemical C can be supplied to the semiconductor manufacturing apparatus 10 more stably and continuously. Additionally, the liquid chemical supply device makes it possible to make a full use of the replaceable canisters in which the introduction of gases G is problematic during replacement; however, the gases G can be processed by the device. Also, by using replacement canisters, the burden of the maintenance of the canisters on a semiconductor manufacturer is reduced. By the removal of the gas or gases G from the liquid chemical that is ultimately supplied to the semiconductor manufacturing apparatus, this device can enable high-quality semiconductors to be manufactured.

The liquid chemical supply device 100 according to the present invention may be a device provided for safely supplying a fixed amount of TEOS, TiCL4, TMA, LTO520, TEMAZr, TEMAHf, HBO, 4MS, 3MS, TEB, TEPO, and so on, which are hazardous liquid materials handled in a CVD (chemical vapor deposition) process, or the like in which coating materials are chemically deposited on the surface of a substrate by using special gases during a semiconductor manufacturing process.

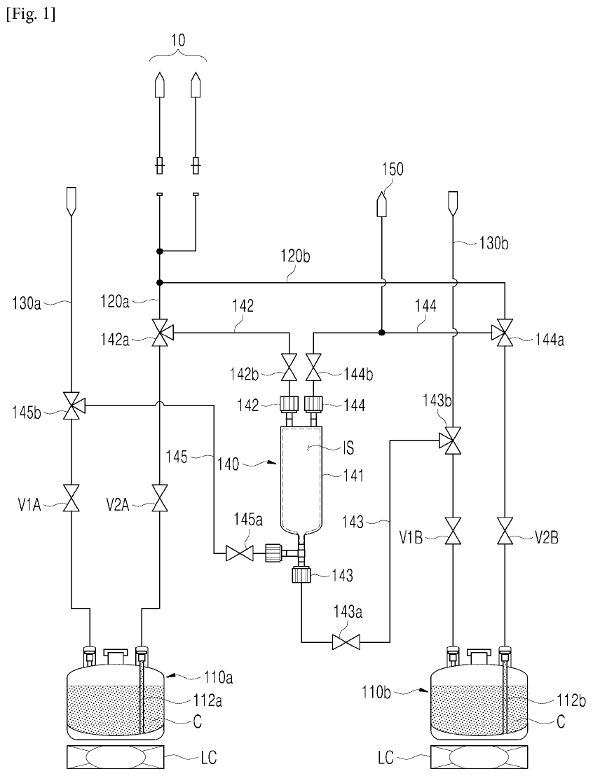

In order to specifically implement the functions or operations as described above, a liquid chemical supply device 100 according to an embodiment of the present invention may comprise first and second canisters 110a and 110b, first and second supply lines 120a and 120b, first and second push lines 130a and 130b, and a gas processing unit 140, as shown in FIG. 1 and may further comprise a control unit (not shown in the Figures).

Here, the first canister 110a, the first supply line 120a, and the first push line 130a form a first supply system AA for providing a liquid chemical C to a semiconductor manufacturing apparatus 10, and the second canister 110b, the second supply line 120b, and the second push line 130b form a second supply system BB for providing the liquid chemical C to the same semiconductor manufacturing apparatus 10. The term semiconductor manufacturing apparatus or manufacturing apparatus will be used, but it is understood that term can be substituted with one or more manufacturing apparatuses or one or more tools. Further, it is understood that the one or more manufacturing apparatuses may be one or more types of the CVD tools as described in the Background of the Invention or other tool requiring the delivery of high purity liquid chemical thereto.

In this case, the first supply system AA and the second supply system BB are only labeled to distinguish the supply systems for providing the liquid chemical C to the semiconductor manufacturing apparatus 10 in parallel and individually from each other in accordance with the operative control of a control unit (not shown) which may be mounted on the liquid chemical supply device 100 or may be an external central control room (not shown), and since each supply system is configured in the same construction as described above, the left and right sides, first supply system AA and second supply system BB, of the embodiment shown in the FIGS. 1-9 may be switched with each other, unlike what is shown.

Hereinafter, features according to the embodiments of the present invention as described above will be described in more detail as follows.

First, the first and second canisters 110a and 110b are typically metal containers provided to safely store therein highly hazardous liquid chemicals C handled in the semiconductor manufacturing apparatus 10, and may be made in the shape of a container having corrosion resistance, impact resistance, or the like and may be connected to the semiconductor manufacturing apparatus 10 by way of the first and second supply lines 120a and 120b to be described later.

In this case, the liquid chemical C stored in the first and second canisters 110a and 110b may be provided to the semiconductor manufacturing apparatus 10 by being forcibly discharged to dip tubes 112a and 112b connected to the first and second supply lines 120a and 120b by the pressure of a push gas PG forced into the canister. A load cell LC may be provided under each canister in order to monitor when the first and second canisters 110a and 110b are to replaced or abnormal operation thereof. The push gas PG may be any of the push gases (or other inert gases) or mixtures thereof as described in the Background of the Invention.

The first and second canisters 110a and 110b may be configured to be freely attachable to and detachable from the liquid chemical supply device 100 according to the embodiment of the present invention, to solve the problems caused by the use of a fixed canister that has been mounted to a chemical supply device, such as in a conventional double tank liquid refillable (DTLR) type.

Accordingly, since the first and second canisters 110a and 110b and refill canisters thereof are provided by a liquid chemical C supplier, the semiconductor manufacturer can rely on the supplier of the liquid chemical C to maintain the canisters in good working order and in compliance with safety regulations.

Gases G introduced into the top of the dip tube 112a and 112b of the canisters or into the supply systems due to the restart of the liquid chemical supply device 100 or the repeated replacements of the canisters 110a and 110b are processed by the gas processing unit 140 in the method described below, and thereby enabling high-quality semiconductors to be manufactured without defects caused by the inflow of the gases G.

The first and second supply lines 120a and 120b are pipe assemblies comprising a plurality of pipes constituting sections, a plurality of VCRs (fasteners) for hermetically connecting therebetween, a regulator (not shown) for maintaining a constant flow rate, and manual/automatic valves V2A, V2B, etc. for controlling flows, where the first supply line 120a connects between the first canister 110a and the semiconductor manufacturing apparatus 10 and the second supply line 120b connects between the second canister 110b and the semiconductor manufacturing apparatus 10.

In this case, for a continuous supply of the liquid chemical C, the first supply line 120a and the second supply line 120b may merge at respective ends thereof to construct a single supply line to the semiconductor manufacturing apparatus 10, as shown in FIG. 1.

These first and second supply lines 120a and 120b may be freely opened and closed by controlling the operation of the automatic valves V2A, V2B, etc. by the control unit (not shown) which may be mounted to the liquid chemical supply device 100 or located in or is part of an external central control room (not shown).

Here, the control unit (not shown) or the external central control room (not shown) is a component that is configured to control the operation of the liquid chemical supply device thereof through the application of electric power to electrical connected valves, valve controllers, sensors or other devices as described below. The control unit can be used to direct the opening and closing of the valves, receive input information, such as process data measured by sensors, signal a canister change, and cause other operational changes to the liquid chemical supply device. The control unit may be implemented as a modular information processing unit such as a micro control unit (MCU), a microcomputer, Arduino, or the like.

In this case, a series of processing procedures of the control unit or the like for controlling each component of the device, or the device, connected thereto and processing transmitted and received data or the like may be performed by coding in a programming language such as C, C++, JAVA, or a machine language that can be recognized by the control unit.

Here, a series of operations and data processing algorithms of the control unit or the like can be readily coded in various ways and forms by a person skilled in the art depending on the purposes, and thus, a detailed description thereof will be omitted.

In order for the supply of the liquid chemical C by the first and second supply lines 120a and 120b described above to be in real time without any interruptions, the pipes of the first and second supply lines 120a and 120b maintain a state of being fully filled with the liquid chemical C at all times through the pressurization of the first and second push lines 130a and 130b and the operative control of the automatic valves V1A, V1B, V2A, V2B, etc., as will be described later.

The first and second push lines 130a and 130b are configured to provide the push gas PG to the first and second canisters 110a and 110b respectively. The first and second push lines 130a and 130b are components provided to generate a positive pressure inside the first and second canisters 110a and 110b respectively for discharging the chemical C to the dip tubes 112a and 112b of the first and second canisters 110a and 110b connected to the first and second supply lines 120a and 120b that are connected to the first and second canisters 110a and 110b, respectively.

Here, the first and second push lines 130a and 130b comprise pipe assemblies including a plurality of pipes constituting sections, a plurality of VCRs (fasteners) for hermetically connecting therebetween, a regulator (not shown) for maintaining a constant flow rate, and manual or automatic valves V1A, V1B, etc. for controlling flows (similarly to the configuration of the supply line 120a and 120b described above) and a supply of compressed push gas (for example from one or more compression units) provided at the ends of the push gas pipe assemblies. Each of the regulator and valves in the push gas pipe assemblies performs its intended operations through the operative control of the control unit described above.

The compression unit is a component configured to send out the push gas PG at a predetermined pressure to the first and second canisters 110a and 110b through the pipe assemblies constituting the first and second push lines 130a and 130b, and may be composed of a compressor for compressing the push gas PG and/or may be composed of a high-pressure tank for accommodating the push gas PG compressed to a predetermined pressure. The compressor, if present, may be controlled by the control unit.

In this case, the push gas PG uses an inert gas of high purity such as argon (Ar), helium (He), hydrogen (H2), and nitrogen (N2), which does not cause a chemical reaction with the liquid chemical C.

As the push gas PG is provided to the inside of the first and second canisters 110a and 110b at a set pressure or is blocked through the operative control of the control unit for the compression unit and/or the automatic valves V1A and V1B of the pipe assemblies, respectively, as described, the stored liquid chemical C may be accurately provided at a fixed amount to the semiconductor manufacturing apparatus 10 through the dip tubes 112a and 112b and the first and second supply lines 120a and 120b, respectively.

The gas processing unit 140 is a component of the liquid chemical supply device provided separately to process the gases G which have been introduced into the first and second supply lines 120a and 120b during the replacement of an empty canister or a malfunctioning canister or damage to the supply systems that results in a decrease of production yield of a semiconductor process. The gas processing unit 140 processes the gases G, such that the gases G are not provided to the semiconductor manufacturing apparatus 10 along with the liquid chemical C.

As described above, in order to process the introduced gases G, for example, the gas G present in the diptube of a replacement canister, which would otherwise be a cause of defects, the present invention processes the gases G in such a way that the chemical C containing the gases G therein is branched off from the first supply line 120a (or the second supply line 120b) to the second push line 130b (or the first push line 130a) and then is stored again in the second canister 110b (or the first canister 110a) using the existing supply lines and the push lines as they are, instead of discharging the gases G to the outside through a separate additional exhaust line.

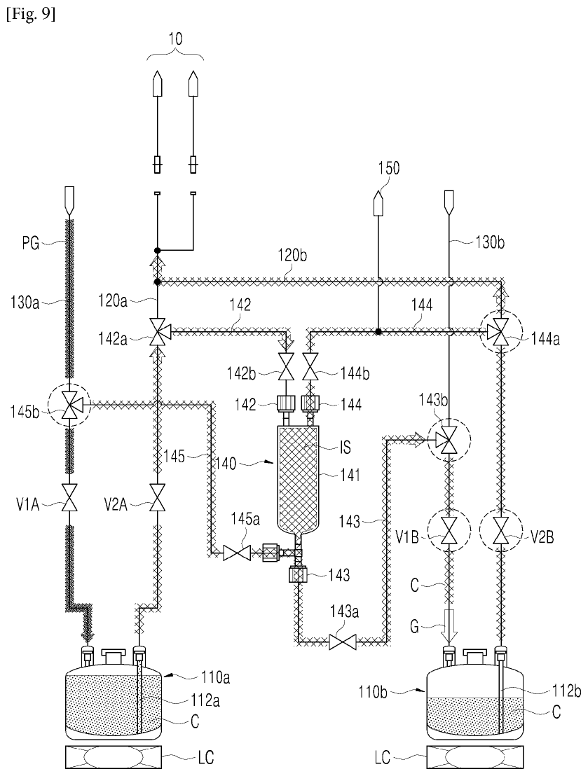

That is, in order to process the gases G in such a way that the chemical C in the first supply line 120a containing the gases G therein is provided to and stored in the second canister 110b through the second push line 130b as shown in FIG. 9, the gas processing unit 140 according to the embodiment of the present invention may be provided (connected) between and in fluid communication with the first supply line 120a and the second push line 130b.

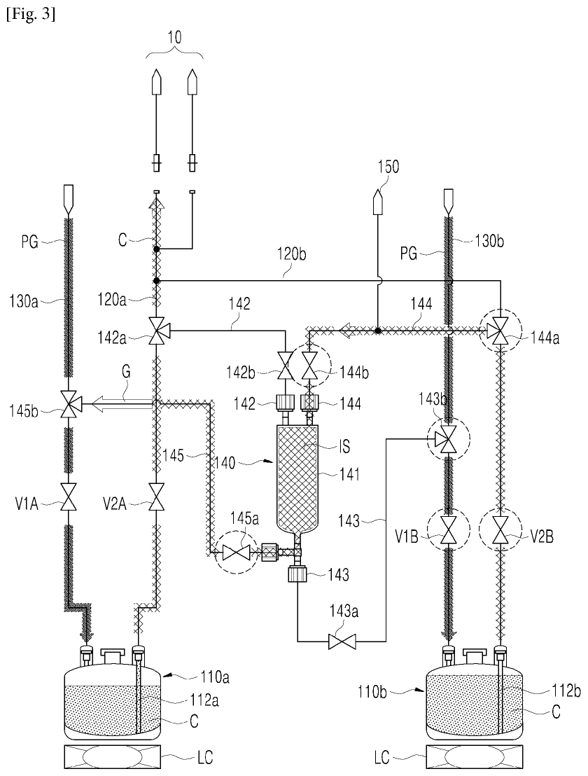

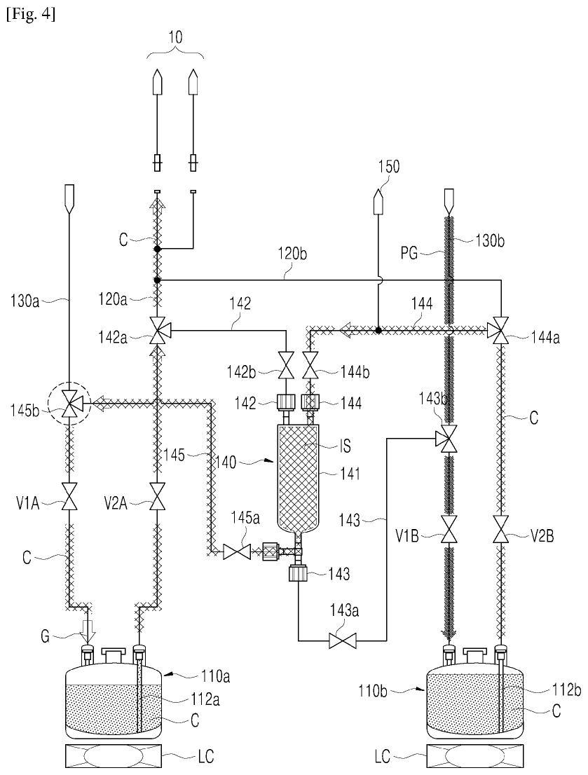

Further, in order to process the gases G in such a way that the chemical C in the second supply line 120b containing the gases G therein is provided to and stored in the first canister 110a through the first push line 130a as shown in FIGS. 3 and 4, the gas processing unit 140 according to the embodiment of the present invention may be provided (connected) between and in fluid communication with the second supply line 120b and the first push line 130a.

Consequently, the gas processing unit 140 according to the embodiment of the present invention may comprise a temporary storage tank 141, a first inlet pipe 142, a first outlet pipe 143, a second inlet pipe 144, a second outlet pipe 145, and one or more control valves therein, etc., respectively, connected between, and in fluid communication with, the first supply line 120a and the second push line 130b and connected between, and in fluid communication with, the second supply line 120b and the first supply line 130a, as shown in FIG. 1, as well as connected between and in fluid communication with, the first supply line 120a and the first push line 120b, and connected between and in fluid communication with, the second supply line 130a and the second push line 130b.

The temporary storage tank 141 is a component configured to receive through one side thereof and temporarily store therein the chemical C containing the gases G therein discharged from the first supply line 120a or the second supply line 120b, and accordingly, the gases G and the liquid chemical C in the first supply line 120a or the second supply line 120b will be flowed or directed via the opening and/or closing of control valves to the temporary storage tank from the first and second supply lines 120a and 120b. The temporary storage tank preferably has a fixed volume corresponding to the interior space (“IS”) of the temporary storage tank.

The temporary storage tank 141 may be made of a material having corrosion resistance and impact resistance, and the size of the interior space IS of the temporary storage tank may be determined by taking into account the volume of the gases G introduced into the first and second supply lines 120a and 120b, the interior volume of the first and second inlet pipes 142 and 144 and first and second outlet pipes 143 and 145, and the like. In some embodiments, the interior volume of the temporary storage tank is less than the interior volume of a canister. In some embodiments, the interior volume of the gas processing unit (for example, comprising the temporary storage tank and first inlet line and second outlet pipe or comprising the temporary storage tank and first and second inlet lines and first and second outlet pipes) is less than the interior volume of a canister. In some embodiments, the interior volume of the gas processing unit (for example, comprising the temporary storage tank and first inlet line and second outlet pipe or comprising the temporary storage tank and first and second inlet lines and first and second outlet pipes) is less than half of the size of the interior volume of a canister.

Here, the “one side” of the temporary storage tank 141 connected to the first supply line 120a or the second supply line 120b does not specifically refer to a particular point, but is preferably on the top side or near the top of the temporary storage tank 141. The first supply line 120a and/or the second supply line 120b are preferably connected to the temporary storage tank 141 and/or or connected to the respective inlet pipe that is connected to the temporary storage tank, above the top side of the temporary storage tank, to allow for the liquid chemical C (containing the gases G therein) to flow by its own weight to and through the temporary storage tank 141. While the liquid chemical C flows through the temporary storage tank 141, the liquid chemical C and the gases G separate assisted by gravity.

The first inlet pipe 142 is a component of tubular shape for selectively communicating between the one side (for example, top side) of the temporary storage tank 141 and the first supply line 120a according to the operation of one or more 1-1 control valves 142a and 142b provided in the first inlet pipe 142.

In this case, the 1-1 control valve 142a, installed at one end of the first inlet pipe 142 in communication with the first supply line 120a, is a three-way valve for selectively connecting three pipes, and is operatively controlled by the control unit (not shown) or the like to completely shut off the flow of the liquid chemical C in three directions, to allow the flow of the liquid chemical C from any one pipe to another pipe only, or to allow the flow of the liquid chemical C from any one pipe to the other two pipes. The control valve 142a, when open in a first position, allows the flow of liquid chemical C from the canister 110a through the first supply line 120a through valve 142a in the first supply line 120a to the manufacturing apparatus 10. Alternatively, the control valve 142a, when open in a second position allows the flow of liquid chemical C from the canister 110a through the first supply line 120a passing through control valve 142a in the first supply line 120a to first inlet pipe 142. The control valve 142a, when open in a third position allows the flow of liquid chemical C from the canister 110a through the first supply line 120a passing through control valve 142a in the first supply line 120a and simultaneously to the manufacturing apparatus 10 and to first inlet pipe 142.

In addition, the 1-1 control valve 142b installed within and/or at the other end of the first inlet pipe 142 in communication with the temporary storage tank 141 is a two-way valve auxiliarily installed together with the three-way valve 142a described above for selectively connecting the two pipes, and is operatively controlled by the control unit (not shown) or the like to completely shut off the flow of the liquid chemical C, or to allow the flow of the liquid chemical C between the two pipes, that is, between the first supply pipe and the first inlet pipe 142.

For these 1-1 control valves 142a and 142b, the object of the present invention may be realized even with only one of the three-way and two-way valves described above, unlike what is shown in FIG. 1.

The first outlet pipe 143 is a component of tubular shape for selectively communicating between the other side (for example, the bottom side) of the temporary storage tank 141 and the second push line 130b according to the operation of one or more control valves 143a and 143b provided in the first outlet pipe 143.

The control valve 143b installed at one end of the first outlet pipe 143 in communication with the second push line 130b is a three-way valve for selectively connecting three pipes, and is operatively controlled by the control unit (not shown) or the like to completely shut off the flow of the liquid chemical C in three directions, to allow the flow of the liquid chemical C from any one pipe to another pipe only, or to allow the flow of the liquid chemical C from any one pipe to the other two pipes.

In addition, the control valve 143a installed within and/or at the other end of the first outlet pipe 143, in communication with the temporary storage tank 141, is a two-way valve auxiliarily installed together with the three-way valve 143b described above for selectively connecting the two pipes, and is operatively controlled by the control unit (not shown) or the like to completely shut off the flow of the liquid chemical C, or to allow the flow of the liquid chemical C between the two pipes. The two pipes referred to in this paragraph are the first outlet pipe and the second push line.

For these 1-2 control valves 143a and 143b as well, the object of the present invention may be realized even with only one of the three-way and two-way valves described above, unlike what is shown in FIG. 1.

When the gases G and a predetermined amount of the liquid chemical C flow from the first supply line 120a into the first inlet pipe 142, the temporary storage tank 141 and the first outlet pipe 143, the gases G may be isolated from the first supply line 120a by the 1-1 control valves 142a and 142b and the 1-2 control valves 143a and 143b, and the semiconductor manufacturing apparatus 10 may be stably provided with only the pure liquid chemical C through the first supply line 120a.

The second inlet pipe 144 is a component of tubular shape for selectively communicating between one side of the temporary storage tank 141 and the second supply line 120b according to the operation of the one or more control valves 144a and 144b provided in the second inlet pipe 144.

The control valve 144a installed at one end of the second inlet pipe 144 in communication with the second supply line 120b is a three-way valve for selectively connecting three pipes, and is operatively controlled by the control unit (not shown) or the like to completely shut off the flow of the liquid chemical C in three directions, to allow the flow of the liquid chemical C from any one pipe to another pipe only, or to allow the flow of the liquid chemical C from any one pipe to the other two pipes. The control valve 144a, when open in a first position, allows the flow of liquid chemical C from the second canister 110b through the second supply line 120b through valve 144a in the first supply line 120a to the manufacturing apparatus 10. Alternatively, the control valve 144a, when open in a second position allows the flow of liquid chemical C from the second canister 110b through the second supply line 120b passing through control valve 144a in the second supply line 120b to second inlet pipe 144. The control valve 144a, when open in a third position allows the flow of liquid chemical C from the second canister 110b through the second supply line 120b passing through control valve 144a in the second supply line 120b and simultaneously to the manufacturing apparatus 10 and to second inlet pipe 144.

In addition, the control valve 144b installed within and/or at the other end of the second inlet pipe 144 in communication with the temporary storage tank 141 is a two-way valve auxiliarily installed together with the three-way valve 144a described above for selectively connecting the two pipes, and is operatively controlled by the control unit (not shown) or the like to completely shut off the flow of the liquid chemical C, or to allow the flow of the liquid chemical C between the two pipes. The two pipes referred to in this paragraph are the second supply line 120b and the second inlet pipe 144.

For these 2-1 control valves 144a and 144b as well, the object of the present invention may be realized even with only one of the three-way and two-way valves described above, unlike what is shown in FIG. 1.

The second outlet pipe 145 is a component of tubular shape for selectively communicating between the other side (preferably opposite the top side, that is preferably the bottom side) of the temporary storage tank 141 and the first push line 130a according to the operation of the one or more control valves 145a and 145b provided on the second outlet pipe 145.

Here, the other side of the temporary storage tank 141 connected to the first and second push lines 130a and 130b does not specifically refer to a particular point, but is preferably a point at the bottom of the temporary storage tank 141. This allows the liquid chemical C (containing the gases G therein) introduced through the top of the temporary storage tank 141 to flow downward, by its own weight, through the interior space IS of the temporary storage tank 141 and branch off through the first or second outlet pipe 143 or 145 to the first or second push line 130a or 130b, respectively.

The control valve 145b installed at one end of the second outlet pipe 145 in communication with the first push line 130a is a three-way valve for selectively connecting three pipes, and is operatively controlled by the control unit (not shown) or the like to completely shut off the flow of the liquid chemical C in three directions, to allow the flow of the liquid chemical C from any one pipe to another pipe only, or to allow the flow of the liquid chemical C from any one pipe to the other two pipes. In operation, control valve 145b, if open, is typically either open in a first position to the push gas flow in first push line 130a through control valve 145b to first canister 110a or open in a second position that allows the flow of the liquid chemical C to flow through second outlet pipe 145 to first push line 130a through control valve 145b to first canister 110a.

In addition, the control valve 145a installed within and/or at the other end of the second outlet pipe 145 in communication with the temporary storage tank 141 is a two-way valve auxiliarily installed together with the three-way valve described above for selectively connecting two pipes, and is operatively controlled by the control unit (not shown) or the like to completely shut off the flow of the liquid chemical C, or to allow the flow of the liquid chemical C between the two pipes. The two pipes referred to in this paragraph are second outlet pipe 145 and first push line 130a.

For these control valves 145a and 145b, the object of the present invention may be realized even with only one of the three-way and two-way valves described above, unlike what is shown in FIG. 1 and so on.

When the gases G and a predetermined amount of the liquid chemical C flow from the second supply line 120b into the second inlet pipe 144, the temporary storage tank 141 and the second outlet pipe 145, the gases G may be isolated from the second supply line 120b by the 2-1 control valves 144a and 144b and the 2-2 control valves 145a and 145b. In this way, the semiconductor manufacturing apparatus 10 may be stably provided with only the pure liquid chemical C through the second supply line 120b.

The gas processing unit 140 comprising the constituents as described above utilizes the supply lines and push lines to perform an initial processing of the liquid chemical C containing the gases G by trapping the gas in a space that is shut off from the first supply line 120a or the second supply line 120b. The processing of the gases G is then completed when the liquid chemical supply device 100 of the present invention pushes or flows the gases G to the first and/or second canisters 110a and/or 110b to be stored therein, through a series of operative control processes to be described below.

Meanwhile, the liquid chemical supply device 100 may be further provided with a vacuum pump 150 which may be used to create a negative pressure inside of the gas processing unit 140 to assist or enable the chemical C containing the gases G therein to smoothly flow from the first and second supply lines 120a and 120b to the gas processing unit 140. The vacuum pump 150 may be briefly operated prior to or when the liquid chemical C containing the gases G therein is flowing to the gas processing unit 140. In alternative embodiments, additional connections between the vacuum pump and the gas processing unit 140 may be provided, such as, in the first inlet pipe 142 if desired.

The vacuum pump 150, as shown, is connected to one side (as shown, the top side) of the gas processing unit 140 and may be operatively controlled by the control unit so that a negative pressure of varying magnitude is generated inside the gas processing unit 140. Accordingly, the flow rate of the liquid chemical C containing the gases G therein flowing into the gas processing unit 140 from the first and second supply lines 120a and 120b may be variously adjusted corresponding to the liquid chemical C flowing into the gas processing unit 140. In addition, the vacuum pump 150 may also be utilized for the purpose of cleaning the inside of the gas processing unit 140 to remove residual liquid chemical C and/or gas G from the inside of the gas processing unit 140. To clean the inside of the gas processing unit, the vacuum pump may be operated when supply of the liquid chemical C through the first and second supply lines 120a and 120b has ended.

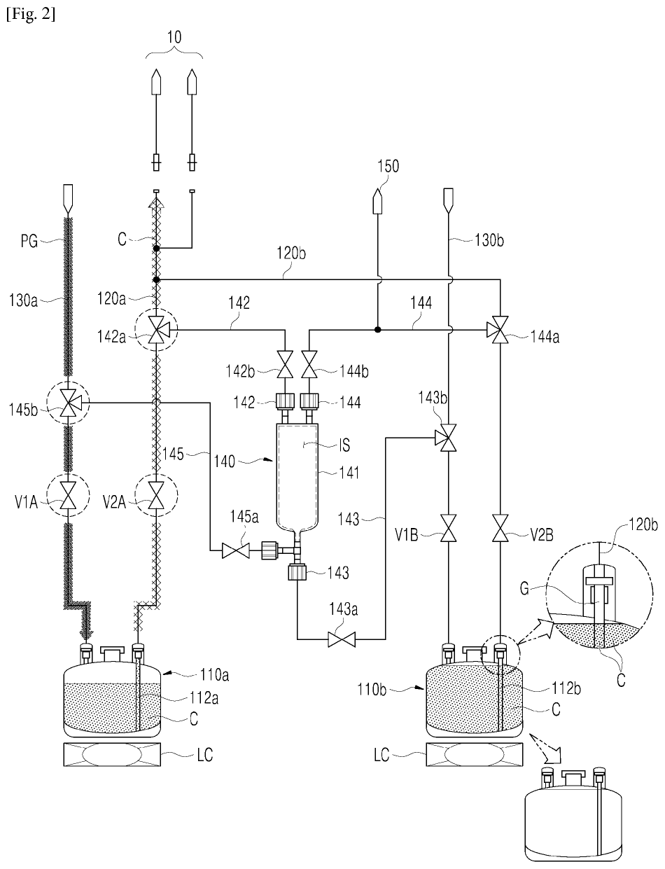

Hereinafter, the liquid chemical supply device shown in FIG. 1 and some methods of using the liquid chemical supply device will be described with reference to FIGS. 2 to 9. More specifically, a series of processes in which the gases G introduced into the first and second supply lines 120a and 120b are processed using the liquid chemical supply device 100 according to the embodiment shown in FIG. 1 will be described below with reference to FIGS. 2 to 9.

In a first method step, the control unit (not shown) mounted to the liquid chemical supply device 100 opens the automatic valve V1A in the first push line 130a, and operatively controls the 2-2 control valve 145b on the side of the first push line 130a and the compressor (or the high-pressure tank or other source for the pressurized push gas) to pressurize the first canister 110a by the push gas PG, as shown in FIG. 2.

In the Figures, the push gas PG is present in the pipes with the dark hashing on the pipes or lines. The liquid chemical, with or without the gases G present therein, is shown as present in the pipes with light hashing.

At the same time or sequentially with this, the control unit opens the automatic valve V2A in the first supply line 120a so that the liquid chemical C in the first canister 110a is supplied to the semiconductor manufacturing apparatus 10 through the dip tube 112a and the first supply line 120a by the pressurization of the push gas PG, while operatively controlling the control valve 142a on the side of the first supply line 120a to provide communication between the first supply line 120a and the semiconductor manufacturing apparatus 10.

While the supply of the liquid chemical C by the first canister 110a is continued as described above, a notification by the load cell LC arranged under the second canister 110b indicates to an operator to perform the operation of replacing the second canister 110b whose liquid chemical C is exhausted with a new second canister 110b which is fully filled and safely managed by the supplier.

In this case, fastening of the new second canister 110b to the liquid chemical supply device 100 is performed in a state in which the corresponding dip tube 112b is exposed to atmospheric pressure, as shown in the enlarged portion of FIG. 2. Accordingly, unless special care is taken, gases G may be introduced into the second supply line 120b.

The second canister 110b whose liquid chemical C is exhausted is collected and maintained by the supplier for reuse in accordance with safety regulations for high pressure containers.

As shown in FIG. 3, the control unit continues the control of the supply of the liquid chemical C by the first canister 110a (as shown in FIG. 2) and at the same time, performs the following simultaneous or sequential control operations so that the gases G introduced by the replaced second canister 110b are sent or flowed from the second supply line 120b to the gas processing unit 140 that forms a separate shutoff or isolation space for an initial processing. To flow the gases G introduced by the replaced second canister 110b to the processing unit 140, the control unit opens the automatic valve V1B in the second push line 130b, and operatively controls the 1-2 control valve 143b in the second push line 130b so that the push gas in second push line 130b is supplied to the second canister 110b and pressurizes the second canister 110b. The push gas, as described above, may be supplied by a compressor or high-pressure tank or the like (none of which are shown).

At the same time or sequentially with the step of supplying the push gas above, the control unit operatively controls the automatic valve V2B in the second supply line 120b, the 2-1 control valve 144a in the second supply line 120b (and connected to the second inlet pipe 144), the 2-1 control valve 144b in the second inlet pipe 144 that is in fluid communication with the temporary storage tank 141, and the 2-2 control valve 145a in the second outlet pipe and in communication with the temporary storage tank 141 so that the liquid chemical C containing the gases G therein that has been discharged into the second supply line 120b through the dip tube 112b by the pressurization of the second push line 130b fills an interior volume defined by and including the second inlet pipe 144, the interior space IS of the temporary storage tank 141, and the second outlet pipe 145. (Control valve 145b is closed to the flow of the liquid chemical C containing the gases G in second outlet pipe 145.)

In the next step, the 2-2 control valve 145b, the three-way control valve, on the first push line 130a is operatively controlled to allow the push gas PG of the first push line 130a to flow to the first canister 110a, but blocks (continues to block) the liquid chemical C containing the gases G filled in the gas processing unit 140 from flowing into the first push line 130a.

While the supply of the liquid chemical C by the first canister 110a is continued by the operative control of the control unit according to FIG. 3, and after the gases G introduced by the newly replaced second canister 110b were sent out (flowed) from the second supply line 120b to the gas processing unit 140 that is a separate shutoff or isolation space (including the temporary storage tank 141, the second inlet pipe 144, and the second outlet pipe 145), the replaced second canister 110b is in a state capable of supplying only the pure liquid chemical C to the semiconductor manufacturing apparatus 10 through the second supply line 120b. The liquid chemical C and gases G go through an initial processing in the gas processing unit 140. The isolation space is established by closing or keeping closed the control valves on the periphery of the isolation space. As shown the isolation space includes the temporary storage tank 141, the second inlet pipe 144, and the second outlet pipe 145; and depending upon how long the control unit requires the liquid chemical to be held in the isolation space, the control valves 145b and 143a and optionally control valve 144a may be closed or remain closed to the flow of the liquid chemical C and the gases G. In alternative embodiments, control valve 144a remains open to the flow of the liquid chemical into the isolation space while control valves 145b and 143a remain closed.

In the next step, the control unit performs a control operation for a second processing as shown in FIG. 4 in which the liquid chemical C and gases G filled in the gas processing unit 140 flow to and are stored in the first canister 110a through the first push line 130a while maintaining the supply of liquid chemical C from the first canister 110a to the semiconductor manufacturing apparatus 10, as shown in FIGS. 3 and 4.

That is, the control unit performs operative control for switching the second control valve 145b on the side of the first push line 130a, so that the supply of the push gas PG to the first canister 110a is blocked while maintaining the supply of the push gas PG to the second canister 110b, (control valve 144a is either opened or remains open) so the liquid chemical C containing the gases G filled in the gas processing unit 140 is stored in the first canister 110a through the first push line 130a.

As a result, the gases G introduced during the replacement of the second canister 110b are not discharged to the outside through a separate pipe, but are ultimately stored in the first canister 110a without being supplied to the semiconductor manufacturing apparatus 10.

And when the operative control of the control unit as described above switches control valve 145b, the liquid chemical C stored in the first canister 110a is discharged from the dip tube 112a of the first canister 110a by an amount corresponding to that of the chemical C being exhausted in real time in the semiconductor manufacturing apparatus 10, so as to be continuously supplied at a fixed amount to the semiconductor manufacturing apparatus 10 via the first supply line 120a even if there is no forced supply of the push gas PG through the first push line 130a, which is caused by the pressure differential generated between the inside of the semiconductor manufacturing apparatus 10 such as a deposition chamber of the semiconductor apparatus in which the chemical C is supplied and exhausted in real time and the inside of the first canister 110a.

Through a series of control operations according to FIGS. 2 to 4 as discussed above, the liquid chemical supply device 100 may provide and store the chemical C of the second supply line 120b containing the gases G therein to the first canister 110a through the first push line 130a, so as to remove the gases G from the chemical C that is ultimately supplied to the semiconductor manufacturing apparatus. (This is referred to as the “other container processing method”).

On the other hand, unlike what is shown in FIGS. 2 to 4, the liquid chemical supply device 100 may also provide and store the chemical C of the second supply line 120b containing the gases G therein to the second canister 110b (not the first canister 110a) through the second push line 130b by the control operation of the gas processing unit 140, as described above, through the control of the control valves 144a and 144b and the control valves 143a and 143b (instead of control valves 145a and 145b) and allowing flow of the chemical liquid into and through the first outlet pipe 145 instead of the second outlet pipe 143, and the second push line 130b instead of the first push line 130a, so as to remove the gases G from the chemical C that is ultimately supplied to the semiconductor manufacturing apparatus. (This is referred to as the “same container processing method”).

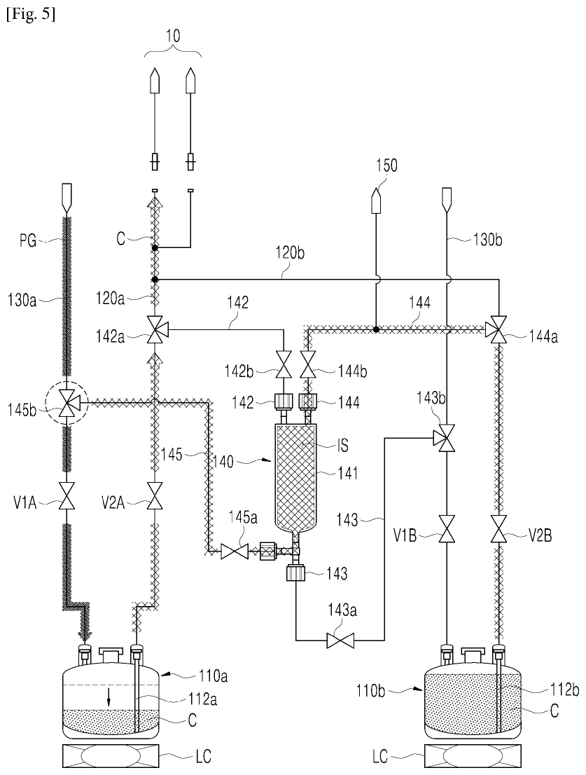

Returning to the other container processing method, as shown in FIG. 5, after the gases G on the side of the second supply line 120b are stored in the first canister 110a, (as determined by the control unit) the control valve 145b is opened to the flow of the push gas and the liquid chemical C of the first canister 110a is continuously supplied to the semiconductor manufacturing apparatus 10 by the first push line 130a until the amount of liquid chemical C in the first canister 110a is less than or equal to the set value. To accomplish this, the control unit specifically operatively controls the compressor or the high-pressure tank and/or the control valve 143b on the side of the second push line 130b, and the automatic valve V1B of the second push line 130b, to block the supply of the push gas PG to the second canister 110b, and at the same time or sequentially, the control unit operatively controls the switching of the compressor (or the high-pressure tank) and/or the control valve 145b on the side of the first push line 130a, and the automatic valve V1A (stays open) on the side of the first push line 130a, so that that the liquid chemical C may be supplied to the semiconductor manufacturing apparatus 10 by way of the dip tube 112a in the first canister 110a and the first supply line 120a through the direct supply of the push gas PG to the first canister 110a.

As a result, the liquid chemical C stored in the first canister 110a may be stably supplied at a fixed amount to the semiconductor manufacturing apparatus 10 so as to be continuously exhausted until it reaches a predetermined set amount (for example, at any amount from about 5 to about 50%, or about 30%).

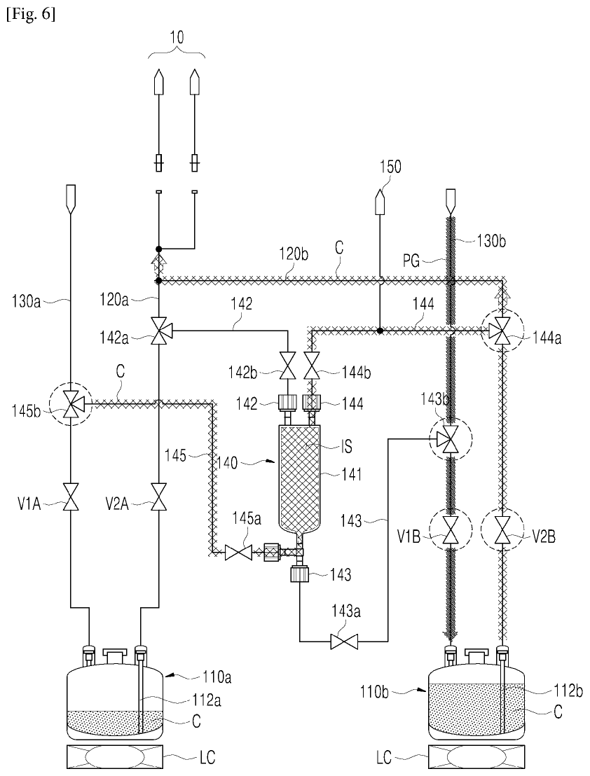

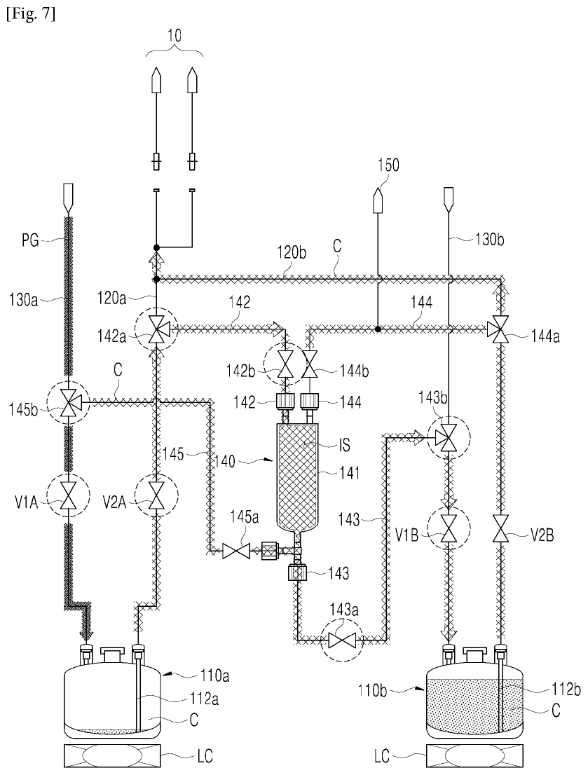

In one embodiment of the method, for stable and continuous supply of the liquid chemical C to the manufacturing apparatus, a set amount or set value for the replacement timing of the canisters 110a and 110b is based on the remaining amount of the liquid chemical C in a canister. When a canister has been exhausted to less than or equal to the set value, a replacement preparation and method is performed as shown and described in accordance with FIGS. 6 to 7. As shown and described, the replacement set amount or set value is multiple set amounts that may be checked by the load cell LC arranged under each canister. When the liquid chemical C remaining in the first canister 110a reaches the set value (about 30%) as described above, the control unit switches the supply system for the semiconductor manufacturing apparatus 10 to the replaced new second canister 110b (from which the liquid chemical C and gases G have been removed from the dip tube 112b by the gas processing unit 140 by the method steps described above) so as to operatively control the stable supply of the liquid chemical C, as shown in FIG. 6. As shown in FIG. 6, the control unit specifically blocks the supply of the push gas PG to the first canister 110a through the operative control of closing of the 2-2 control valve 145b in the first push line 130a, and closing the automatic valve V1A on the side of the first push line 130a and, if necessary, switching off the compressor (or the high-pressure tank). At the same time or sequentially with this, the control unit forces a direct supply of the push gas PG to the second canister 110b through the opening of the 1-2 control valve 143b in the second push line 130b, the opening of automatic valve V1B in the second push line 130b, and by switching on, if necessary, the compressor (or the high-pressure tank) for the push gas PG. Further, at the same time or sequentially, the automatic valve V2B and the 2-1 control valve 144a in the second supply line 120b are opened. Further, at the same time or sequentially the three-way control valve 144a in the second supply line 120b is operatively controlled to allow the liquid chemical C of the second canister 110b to flow through the dip tube 112b and the second supply line 120b to the semiconductor manufacturing apparatus 10, but to block the liquid chemical C in the gas processing unit 140 from flowing into the second supply line 120b.

In the next method steps, as shown in FIG. 7, while maintaining the supply of the liquid chemical C from the second canister 110b to the semiconductor manufacturing apparatus 10, the control unit performs a control operation of to transfer the remaining liquid chemical C in the first canister 110a to the second canister 110b until the amount of the liquid chemical C remaining in the first canister 110a is exhausted. To accomplish this, the control unit operatively controls the compressor (or the high-pressure tank) of the push gas PG if necessary, and opens the 2-2 control valve 145b in the first push line 130a, and opens the automatic valve V1A in the first push line 130a, to pressurize the first canister 110a by the push gas PG while blocking the supply of the push gas PG to the second canister 110b via control valve 143b. At the same time or sequentially with this, the control unit operatively opens the automatic valve V2A in the first supply line 120a, opens the 1-1 control valves 142a and 142b in the first inlet pipe 142 to allow for the flow of the liquid chemical from the first supply line 120a to the temporary storage tank 141. At the same time or sequentially, the control unit opens the 1-2 control valves 143a and 143b connecting the temporary storage tank 141 and the second push line 130b, and opens the automatic valve V1B, so that the remaining amount of the liquid chemical C discharged into the first supply line 120a flows through the dip tube 112a by the pressurization of the first push line 130a and flows to and is stored in the second canister 110b, by flowing to and through the first inlet pipe 142, the temporary storage tank 141, the first outlet pipe 143 and through the second push line 130b. During the steps to empty canister 110a, the 1-1 control valve 142a (the three-way control valve) is controlled to allow the remaining amount of the chemical C of the first canister 110a to flow to the temporary storage tank 141 but blocks the liquid chemical C from being directly supplied to the semiconductor manufacturing apparatus 10 and control valve 143b blocks the supply of push gas PG to cannister 110b. During this time, the liquid chemical C stored in the second canister 110b is automatically discharged from the dip tube 112b of the second canister 110b by an amount corresponding to that of the chemical C being exhausted in real time in the semiconductor manufacturing apparatus 10, so as to be continuously supplied at a fixed amount to the semiconductor manufacturing apparatus 10 by flowing through the supply line 120b, even if there is no forced supply of the push gas PG through the second push line 130b. The pressure differential generated between the inside of the semiconductor manufacturing apparatus 10 such as the deposition chamber in which the chemical C is supplied and exhausted in real time and the inside of the second canister 110b that causes the liquid chemical C to flow from the second canister 110b to the semiconductor manufacturing apparatus 10.

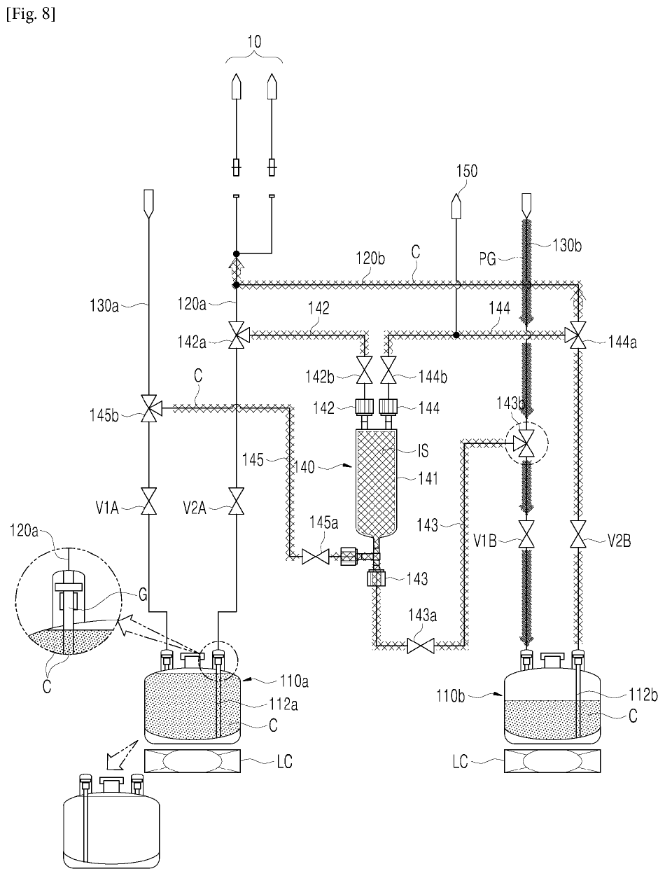

When the amount of the liquid chemical C remaining in the first canister 110a after supplying it to the second canister 110b has been exhausted to a predetermined set value, such as to about 5% remaining in the first canister 110a, the first canister 110a is ready for replacement, and the supply of the liquid chemical C by the second canister 110b to the semiconductor manufacturing apparatus 10 may be continued as follows. When the liquid chemical C of the first canister 110a is exhausted to the predetermined set value which is preferably measured and notified to the control unit by the load cell LC provided under the canister, the control unit closes all of the control valves in the first push line 130a and the first supply line 120a, that is, control valves 145b, V1A and V2A, for replacement of the first canister 110a, as shown in FIG. 8. At the same time or sequentially with the closing of the control valves in the first push line 130a and the first supply line 120a, the control unit operatively controls the switching of the compressor (or the high-pressure tank) and/or the 1-2 control valve 143b on the second push line 130b to supply push gas PG to second canister 110b, so that the liquid chemical C may be continuously forcibly supplied to the semiconductor manufacturing apparatus 10 through pressurization of the second canister 110b by the push gas PG flowing in the second push line 130b to the second canister 110b. As a result, the liquid chemical C in the second canister 110b, at least partially replenished with the remaining amount of the liquid chemical C from the first canister 110a, may be stably and continuously supplied (at a fixed amount, if desired) to the semiconductor manufacturing apparatus 10.

While the supply of the liquid chemical C by the second canister 110b continues as described above, the first canister 110a whose liquid chemical C was exhausted, as indicated by the load cell LC provided under the canister, is replaced with a new first canister 110a which is full of liquid chemical C and gases G above the level of the liquid chemical. When replacing the first canister 110a, the dip tube 112a of the new first canister 110a is exposed to atmospheric pressure, as shown in the enlarged portion of FIG. 8 when the first canister 110a is coupled with the first supply line 120a, and accordingly, causes an introduction of gases G into the first supply line (120a), unless special care is taken.

As the control unit controls the supply of the liquid chemical C by the second canister 110b to be continued as shown in FIG. 8, the control unit performs the following simultaneous or sequential control operations so that the gases G introduced by the replaced first canister 110a are sent out from the first supply line 120a to the gas processing unit 140 that forms a separate shutoff or isolation space for an initial processing, as shown in FIG. 9. The control unit operatively controls, if necessary, the compressor, (or the high-pressure tank) to supply the push gas PG, and opens the 2-2 control valve 145b on the first push line 130a, and opens the automatic valve V1A in the first push line 130a, and so as to pressurize the first canister 110a by the push gas PG. Additionally, at the same time or sequentially, the control unit operatively controls the automatic valve V2A and the 1-1 control valve 142a in the first supply line 120a, the 1-1 control valve 142b in the first inlet pipe 142 connected to the one side (the top side) of the temporary storage tank 141, and the 1-2 control valve 143a so that the liquid chemical C containing the gases G therein that has been discharged into the first supply line 120a through the dip tube 112a by the pressurization of the first push line 130a fills the first inlet pipe 142, the interior space IS of the temporary storage tank 141, and the first outlet pipe 143.

In this case, the control valve 142a, the three-way control valve, in the first supply line 120a is operatively controlled to allow the liquid chemical C containing the gases G therein in the first supply line 120a to flow to the temporary storage tank 141, but blocks it from flowing to the semiconductor manufacturing apparatus 10. And, the control unit operatively controls the control valve 143b and the automatic valve V1B connected to or in the second push line 130b so that the liquid chemical C containing the gases G therein, filled inside the gas processing unit 140 flows to the second canister 110b through the second push line 130b to be stored in the second canister 110b, in the same way, but in the opposite direction as described above in reference to FIGS. 3-5 for the flow of the liquid chemical from the second canister 110a to the first canister 110b. The three-way control valve 143b in the second push line 130b is operatively controlled so that the liquid chemical C containing the gases G flows through control valve 143b from the first outlet pipe 143 into the second push line 130b and into the second canister 110b. The liquid chemical C stored in the second canister 110b continues to flow through the dip tube 112b of the second canister 110b to and through the supply line 120b to the semiconductor manufacturing apparatus 10in an amount corresponding to that of the chemical C being exhausted in real time in the semiconductor manufacturing apparatus 10, even if there is no forced supply of the push gas PG through the second push line 130b. The flow of the liquid chemical C from the second canister 110b through the supply line 120b to the semiconductor manufacturing apparatus 10 is caused by the pressure differential generated between the inside of the second canister 110b and the inside of the semiconductor manufacturing apparatus 10 (such as the deposition chamber) in which the chemical C is supplied and exhausted in real time.

Through a series of control operations (method steps) according to FIGS. 8 to 9 as discussed above, the liquid chemical supply device 100 may provide and store the chemical C of the first supply line 120a containing the gases G therein to the second canister 110b through the second push line 130b, so as to remove the gases G from the chemical C that is ultimately supplied to the semiconductor manufacturing apparatus. (The steps described in accordance with FIGS. 8 and 9 is an “other container processing method”).

On the other hand, unlike what is shown in FIGS. 8 to 9, the liquid chemical supply device 100 may also provide and store the chemical C of the first supply line 120a containing the gases G therein to the first canister 110a through the first push line 130a by the control operation of the gas processing unit 140, or more specifically, of the 1-1 control valves 142a and 142b and the 2-2 control valves 145a and 145b, as described above while utilizing the existing supply lines and the push lines as they are, so as remove the gases G from the chemical C that is ultimately supplied to the semiconductor manufacturing apparatus in a same container processing method.

Returning to the other container processing method, described in accordance with FIG. 9. While the supply of the liquid chemical C by the second canister 110b is continued by the operative control of the control unit, the gases G introduced by the newly replaced first canister 110a would flow through the first supply line 120a with liquid chemical C form the first canister 110a to the gas processing unit 140, which is a separate shutoff space (specifically, the temporary storage tank 141, the first inlet pipe 142, and the first outlet pipe 143), and are subsequently sent out to the inside of the second canister 110b. At this time, the replaced first canister 110a is in a standby state capable of supplying only the pure liquid chemical C to the semiconductor manufacturing apparatus 10 through the first supply line 120a.

Any description herein regarding a component part of or method steps performed by the first supply system AA when the first supply system AA is supplying liquid chemical, applies to the corresponding part in the second supply system BB when the second supply system BB is supplying liquid chemical, and vice versa. Additionally, any description herein regarding a component part of or the steps performed by the first supply system AA when the first supply system is storing liquid chemical, applies to the corresponding part and method steps performed by the second supply system BB when the second supply system is storing liquid chemical, and vice versa.

While specific embodiments of the present invention have been described and illustrated in the above, it will be apparent to a person skilled in the art that the invention is not limited to the embodiments described and various modifications and variations can be made without departing from the spirit and scope of the invention. Therefore, such modifications or variations are not to be understood separately from the technical perspective or spirit of the present invention, and the modified embodiments shall fall within the claims of the present invention.

### INDUSTRIAL APPLICABILITY

The liquid chemical supply device system according to the embodiments of the present disclosure is industrially applicable in that since, the liquid chemical can be supplied to the semiconductor manufacturing apparatus more stably and continuously by using a gas processing unit, and it is possible to make full use of the chemical in the replaceable canister in which the introduction of gases is problematic during each replacement, to put the responsibility for maintenance of the reusable canisters on the chemical supplier, and furthermore, removing the gases from the liquid chemical that is ultimately supplied to the semiconductor manufacturing apparatus which enables the manufacture of high quality semiconductors.

1. A liquid chemical supply device capable of processing a gas, comprising:
first and second canisters connected, respectively, to a semiconductor manufacturing apparatus by way of first and second supply lines, to provide liquid chemicals stored therein to the semiconductor manufacturing apparatus;
first and second push lines connected to the first and second canisters, respectively, and configured to discharge the chemicals into the first and second supply lines, by providing a push gas to the first and second canisters, respectively; and
a gas processing unit in fluid communication between the first supply line and the second push line, in order for the chemical in the first supply line containing a gas therein to be provided to and stored in the second canister through the second push line.

2. The liquid chemical supply device capable of processing a gas of claim 1,
wherein the gas processing unit comprises:
a temporary storage tank configured to receive through one side thereof and accommodate therein the chemical discharged from the first supply line with a gas contained therein;
a first inlet pipe configured to selectively communicate between the one side of the temporary storage tank and the first supply line in accordance with operation of one or more control valves provided in the first inlet pipe; and
a first outlet pipe configured to selectively communicate between the other side of the temporary storage tank and the second push line in accordance with operation of one or more control valves provided in the first outlet pipe.

3. The liquid chemical supply device capable of processing a gas of claim 2,
wherein the temporary storage tank is configured to receive through the one side thereof and accommodate therein the chemical discharged from the second supply line with a gas contained therein, in order for the chemical in the second supply line containing a gas therein to be provided to and stored in the first canister through the first push line, and
wherein the gas processing unit further comprises:
a second inlet pipe configured to selectively communicate between the one side of the temporary storage tank and the second supply line in accordance with operation of one or more control valves provided in the second inlet pipe; and
a second outlet pipe configured to selectively communicate between the other side of the temporary storage tank and the first push line in accordance with operation of one or more control valves provided in the second outlet pipe.

4. The liquid chemical supply device capable of processing a gas of claim 3,
wherein the liquid chemical supply device provides the chemical in the first supply line containing a gas therein to the second canister to be stored therein through the second push line in accordance with operation of the one or more control valves in the first inlet pipe and the one or more control valves in the first outlet pipe, so as to remove the gas from the chemical that is ultimately supplied to the semiconductor manufacturing apparatus.

5. The liquid chemical supply device capable of processing a gas of claim 3,
wherein the liquid chemical supply device provides the chemical in the second supply line containing a gas therein to the first canister to be stored therein through the first push line by control operation of the one or more control valves in the second inlet pipe and the one or more control valves in the second outlet pipe, so as to remove the gas from the chemical that is supplied to the semiconductor manufacturing apparatus.

6. The liquid chemical supply device capable of processing a gas of claim 3,
wherein the liquid chemical supply device provides the chemical in the first supply line containing a gas therein to the first canister to be stored therein through the first push line by control operation of the one or more control valves in the first inlet pipe and the one or more control valves in the second outlet pipe, so as to remove the gas from the chemical that is supplied to the semiconductor manufacturing apparatus.

7. The liquid chemical supply device capable of processing a gas of claim 3,
wherein the liquid chemical supply device provides the chemical in the second supply line containing a gas therein to the second canister to be stored therein through the second push line by control operation of the one or more control valves in the second inlet pipe and the one or more control valves that are in the first outlet pipe, so as to remove the gas from the chemical that is supplied to the semiconductor manufacturing apparatus.

8. The liquid chemical supply device capable of processing a gas of any of the preceding claims, wherein a vacuum pump configured to cause an interior of the gas processing unit to be in a negative pressure is further connected to the one side of the gas processing unit, so as to allow the chemical containing a gas therein to flow smoothly from the first and second supply lines to the gas processing unit.

9. The liquid chemical supply device capable of processing a gas of any of the preceding claims, wherein the first canister and the second canister are detachably connected to said liquid supply device for replacement of the first canister and the second canister with a full first canister and a full second canister.

10. The liquid supply device capable of processing a gas of claim 9, further
wherein the full first canister and full second canister each comprise a diptube and the gas is an inert gas located in the diptube of the full first canister and full second canister.

11. The liquid supply device capable of processing a gas of any of the preceding claims further comprising a control unit.

12. The liquid supply device capable of processing a gas of any of the preceding claims further comprising a load cell located below the first canister and the second canister.

13. A system for supplying a liquid chemical comprising the liquid supply device of any of the preceding claims and one or more semiconductor manufacturing apparatuses.

14. The system of claim 11, wherein said one or more semiconductor manufacturing apparatuses are one or more CVD tools.

15. The system of claim 11 or 12, wherein said liquid chemical is selected from high purity TEOS, TiCL4, TMA, LTO520, TEMAZr, TEMAHf, HBO, 4MS, 3MS, TEB, or TEPO.

16. The method of processing a gas, comprising the steps of:
providing the liquid chemical supply device or system of any of the preceding claims;
flowing a push gas in said first push line to said first canister having said liquid chemical and said gas therein, and thereby flowing from said first canister said liquid chemical containing said gas to a first supply line;
flowing said liquid chemical containing said gas from said first supply line to said gas processing unit;
flowing said liquid chemical containing said gas from said gas processing unit through a second push line into said second canister; and
storing said liquid chemical containing said gas in said second canister.

17. The method of claim 16, further comprising the step of supplying said one or more semiconductor apparatuses from said second canister while simultaneously performing the step of flowing said liquid chemical containing said gas from said gas treatment unit through said second push line into said second canister.

18. The method of claim 17, further comprising the step of temporarily blocking the flow of the push gas in the second push line while performing the step of flowing said liquid chemical containing said gas from said gas treatment unit through said second push line into said second canister.

19. The method of claim 18, further comprising the step of: switching the supply of the liquid chemical from the second canister to the first canister when the level in the second canister reaches a set value, by flowing push gas through the first push line and into the first canister.

20. The method of claim 19, further comprising the step of: flowing push gas into the second canister to flow liquid chemical present in the second canister through the gas processing unit and into the first canister while the first canister continues to supply the one or more semiconductor apparatuses until the second canister is exhausted.

21. The method of claim 20, further comprising the steps of: terminating the flow of the push gas to the second canister; flowing the push gas to the first canister; and replacing the exhausted second canister while continuing to flow push gas into the first canister to flow liquid chemical present in the first canister to the one or more semiconductor apparatuses.
